(19) United States
(12) Patent Application Publication
(10) Pub. No.: US 2025/0301857 A1
(43) Pub. Date: Sep. 25, 2025

(54) DISPLAY DEVICE

(71) Applicant: Samsung Display Co., LTD., Yongin-si (KR)

(72) Inventors: Sun Kwun SON, Yongin-si (KR); Na Hyeon CHA, Yongin-si (KR)

(21) Appl. No.: 19/015,372

(22) Filed: Jan. 9, 2025

(30) Foreign Application Priority Data
Mar. 19, 2024 (KR) 10-2024-0038000

(51) Int. Cl. H10K 59/121; G02B 27/01; H10K 59/131

(52) U.S. Cl. CPC H10K 59/1213; G02B 27/0172; H10K 59/1216; H10K 59/131; G02B 2027/0178

(57) ABSTRACT

A display device includes a first pixel disposed in a first row and a first column, a second pixel disposed in the first row and a second column next to the first column, a third pixel disposed in a second row next to the first row and the first column, a fourth pixel disposed in the second row and the second column, a first scan line extending in a first direction between the first row and the second row, and a first gate pattern connected to the first scan line. The first gate pattern includes a gate electrode of a transistor of each of the first to fourth pixels.

This application claims priority to Korean Patent Application No. 10-2024-0038000, filed on Mar. 19, 2024, and all the benefits accruing therefrom under 35 U.S.C. § 119, the content of which in its entirety is herein incorporated by reference.

### BACKGROUND

### 1. Field

Embodiments of the invention relate to a display device.

### 2. Description of the Related Art

As the information-oriented society evolves, various demands for display devices are ever increasing. For example, display devices are being employed by a variety of electronic devices such as smart phones, digital cameras, laptop computers, navigation devices, and smart televisions. Display devices may be flat panel display devices such as a liquid-crystal display device, a field emission display device, and an organic light-emitting display device. Among such flat panel display devices, a light-emitting display device includes a light-emitting element that can emit light on its own, so that each of the pixels of the display panel can emit light by themselves. Accordingly, a light-emitting display device can display images without a backlight unit that supplies light to the display panel.

### SUMMARY

Embodiments of the invention provide a display device in which the area of pixel circuits is reduced by reducing the number of scan lines for implementing a high-resolution display device.

An embodiment of the invention provides a display device including a first pixel disposed in a first row and a first column, a second pixel disposed in the first row and a second column next to the first column, a third pixel disposed in a second row next to the first row and the first column, a fourth pixel disposed in the second row and the second column, a first scan line extending in a first direction between the first row and the second row, and a first gate pattern connected to the first scan line. In such an embodiment, the first gate pattern includes a gate electrode of a transistor of each of the first to fourth pixels.

In an embodiment, the display device may further include a second scan line disposed on a lower side of the second row and extending in the first direction, and a second gate pattern connected to the second scan line. In such an embodiment, the second gate pattern may include a gate electrode of another transistor of each of the third and fourth pixels.

In an embodiment, the display device may further include an initialization voltage line which supplies an initialization voltage, a driving voltage line which supplies a driving voltage, and a data line which supplies a data voltage. In such an embodiment, each of the first to fourth pixels may include a light-emitting element disposed on a substrate, a first transistor which supplies a driving current to a second node connected to a first electrode of the light-emitting element, based on a voltage of a first node connected to a gate electrode thereof, a first capacitor connected between the first node and the initialization voltage line, a second transistor connected to the first node, a second capacitor connected between the data line and a third node connected to a drain electrode of the second transistor, and a third transistor connected between the third node and the second node.

In an embodiment, the first scan line may supply a first scan signal to the third transistor of the first pixel, the third transistor of the second pixel, the second transistor of the third pixel and the second transistor of the fourth pixel through the first gate pattern.

In an embodiment, the second scan line may supply a second scan signal to the third transistor of the third pixel and the third transistor of the fourth pixel through the second gate pattern.

In an embodiment, the display device may further include an active layer disposed on the substrate and comprising a semiconductor region of each of the first to third transistors, a first gate layer disposed on the active layer and comprising the gate electrode of each of the first to third transistors, a second gate layer disposed on the first gate layer and comprising the first and second scan lines, a first source metal layer disposed on the second gate layer, and a second source metal layer disposed on the first source metal layer.

In an embodiment, the first gate pattern may be defined by the first gate layer and include the gate electrode of the third transistor of the first pixel, the gate electrode of the third transistor of the second pixel, the gate electrode of the second transistor of the third pixel, and the gate electrode of the second transistor of the fourth pixel.

In an embodiment, the second gate pattern may be defined by the first gate layer and may include the gate electrode of the third transistor of the third pixel and the gate electrode of the third transistor of the fourth pixel.

In an embodiment, the initialization voltage line may include a first defined by the second gate layer and extending in the first direction, and a second portion defined by the second source metal layer, intersecting the first direction, and connected to the first portion.

In an embodiment, a first electrode of the first capacitor may include the gate electrode of the first transistor, and a second electrode of the first capacitor may be a portion of the first portion of the initialization voltage line.

In an embodiment, the display device may further include a capacitor electrode disposed on the second source metal layer. In such an embodiment, the data line may be defined by the first source metal layer. In such an embodiment, a first electrode of the second capacitor may be the capacitor electrode, and a second electrode of the second capacitor may be a portion of the data line.

An embodiment of the invention provides a display device including a first pixel disposed in a first row and a first column, a second pixel disposed in the first row and a second column next to the first column, a third pixel disposed in the first row and a third column next to the second column, a fourth pixel disposed in a second row next to the first row and the first column, a fifth pixel disposed in the second row and second column, a sixth pixel disposed in the second row and third column, a first scan line extending in a first direction between the first row and the second row, a first gate pattern connected to the first scan line and overlapping with the second, third, fifth and sixth pixels, and a driving voltage line extending between the first column and the second column in a second direction intersecting the first direction. In such an embodiment, the driving voltage line supplies a driving voltage to the first, second, fourth and fifth pixels.

In an embodiment, the display device may further include an initialization voltage line which supplies an initialization voltage, and a data line which supplies a data voltage. In such an embodiment each of the first to sixth pixels may include a light-emitting element disposed on a substrate, a first transistor which supplies a driving current to a second node connected to a first electrode of the light-emitting element based on a voltage of a first node connected to a gate electrode thereof, a first capacitor connected between the first node and the initialization voltage line, a second transistor connected to the first node, a second capacitor connected between the data line and a third node connected to a drain electrode of the second transistor, and a third transistor connected between the third node and the second node.

In an embodiment, a source electrode of the first transistor of the first pixel and a source electrode of the first transistor of the second pixel may be formed integrally with each other as a single unitary indivisible part. In such an embodiment, the driving voltage line may supply a driving voltage to the source electrode of the first transistor of each of the first and second pixels.

In an embodiment, the first gate pattern may include a gate electrode of the third transistor of the second pixel, a gate electrode of the third transistor of the third pixel, a gate electrode of the second transistor of the fifth pixel, and a gate electrode of the second transistor of the sixth pixel.

In an embodiment, the display device may further include a second scan line disposed on a lower side of the second row and extending in the first direction, and a second gate pattern connected to the second scan line. In such an embodiment, the second gate pattern may overlap the fifth and sixth pixels.

In an embodiment, the first gate pattern may include a gate electrode of the third transistor of the fifth pixel and a gate electrode of the third transistor of the sixth pixel.

In an embodiment, the display device may further include an active layer disposed on the substrate and comprising a semiconductor region of each of the first to third transistors, a first gate layer disposed on the active layer and comprising a gate electrode of each of the first to third transistors, a second gate layer disposed on the first gate layer and comprising the first and second scan lines, a first source metal layer disposed on the second gate layer, and a second source metal layer disposed on the first source metal layer.

In an embodiment, the initialization voltage line may include a first portion defined by the second gate layer and extending in the first direction, and a second portion defined by the second source metal layer, intersecting the first direction, and connected to the first portion.

In an embodiment, a first electrode of the first capacitor may include the gate electrode of the first transistor. In such an embodiment, a second electrode of the first capacitor may be a part of the first portion of the initialization voltage line.

In embodiments according to the invention, a scan line supplies a scan signal to transistors of pixels arranged in rows and columns through a single gate pattern, such that the number of scan lines can be reduced, thereby reducing the area of the pixel circuits. As a result, it is possible to implement a high-resolution display device.

### BRIEF DESCRIPTION OF THE DRAWINGS

These and/or other features of the invention will become apparent and more readily appreciated from the following description of the embodiments, taken in conjunction with the accompanying drawings, in which:

FIG. 1 is a view showing a virtual reality device including a display device according to an embodiment.

FIGS. 2 and 3 are views showing a head-mounted display device including a display device according to an embodiment.

FIG. 4 is a circuit diagram showing a pixel of a display device according to an embodiment of the disclosure.

FIG. 5 is a view showing an arrangement of pixels in a display device according to an embodiment of the disclosure.

FIG. 6 is a view showing some layers of the view of FIG. 5.

FIG. 7 is a view showing some other layers of the view of FIG. 5.

FIG. 8 is a view showing one of the pixels of FIG. 5.

FIG. 9 is a view showing some layers of the view of FIG. 8.

FIG. 10 is a view showing some other layers of the view of FIG. 8.

FIG. 11 is a cross-sectional view showing a pixel in a display device according to an embodiment of the disclosure.

### DETAILED DESCRIPTION

The invention will now be described more fully hereinafter with reference to the accompanying drawings, in which various embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. The same reference numbers indicate the same components throughout the specification. In the attached drawing figures, the thickness of layers and regions is exaggerated for clarity.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will also be understood that when a layer is referred to as being “on” another layer or substrate, it can be directly on the other layer or substrate, or intervening layers may also be present. In contrast, when an element is referred to as being “directly on” another element, there are no intervening elements present.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” “At least one of A and B” or “at least one selected from A and B” means “A and/or B.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system).

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. A region illustrated or described as flat may, typically, have rough and/or nonlinear features, for example. Moreover, sharp angles that are illustrated may be rounded. Thus, the regions illustrated in the drawing figures are schematic in nature and their shapes are not intended to illustrate the precise shape of a region and are not intended to limit the scope of the present claims.

Hereinafter, embodiments of the invention will be described in detail with reference to the accompanying drawings.

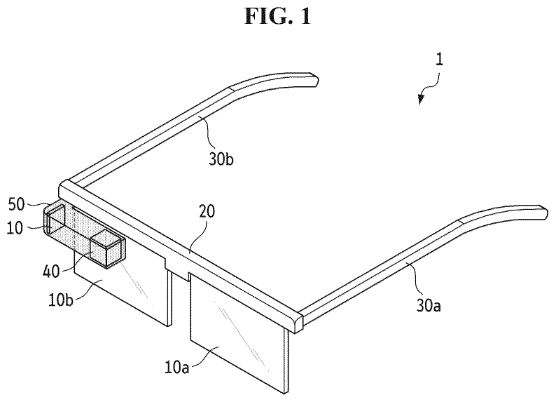

FIG. 1 is a view showing a virtual reality device including a display device according to an embodiment.

Referring to FIG. 1, an embodiment of a virtual reality device 1 may be a glasses-type device. The virtual reality device 1 may include a display device 10, a left eye lens 10a, a right eye lens 10b, a support frame 20, eyeglass temples 30a and 30b, a reflective member 40, and a display device case 50.

In another embodiment, the virtual reality device 1 may be applied to a head-mounted display (HMD) including a band that can be worn on the head instead of the temples 30a and 30b. Accordingly, it would be understood that the virtual reality device 1 is not limited to that shown in FIG. 1 but may be applied in a variety of electronic devices in a variety of forms.

The display device case 50 may include the display device 10 and the reflective member 40, that is, the display device 10 and the reflective member 40 may be disposed in the display device case 50. An image displayed on the display device 10 may be reflected by the reflective member 40 and provided to the user's right eye through the right eye lens 10b. Accordingly, the user may watch a virtual reality image displayed on the display device 10 through the right eye.

In an embodiment, as shown in FIG. 1, the display device case 50 may be disposed at the right end of the support frame 20, but the position of the case 50 is not limited thereto. In another embodiment, for example, the display device case 50 may be disposed at the left end of the support frame 20. In such an embodiment, an image displayed on the display device 10 is reflected by the reflective member 40 and provided to the user's left eye through the left eye lens 10a. Accordingly, the user may watch a virtual reality image displayed on the display device 10 through the left eye.

In another embodiment, for example, the display device cases 50 may be disposed at both the left and right ends of the support frame 20, respectively. In such an embodiment, the user can watch a virtual reality image displayed on the display device 10 through both the left and right eyes.

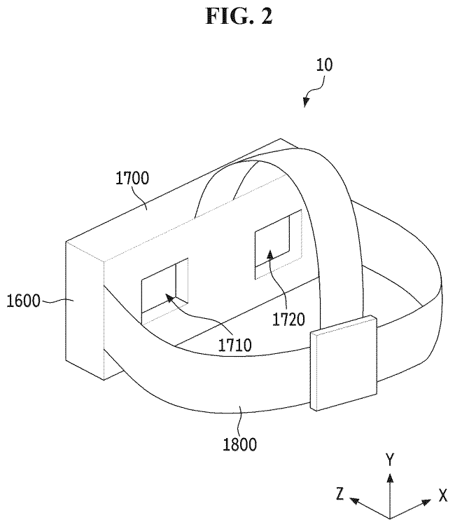

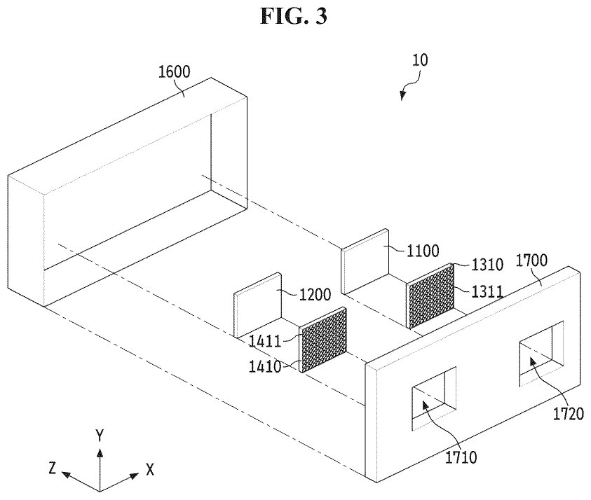

FIGS. 2 and 3 are views showing a head-mounted display device including a display device according to an embodiment.

Referring to FIGS. 2 and 3, an embodiment of a display device 10 may be applied to a head-mounted display (HMD). A first display device 1100 may provide images to the user's right eye, and a second display device 1200 may provide images to the user's left eye. A display surface of the first display device 1100 and the second display device 1200 may be on a plane defined by an X-axis direction (or a first direction) and a Y-axis direction (or a second direction). Here, Z-axis direction (or a third direction) may be a direction perpendicular to the X-axis direction and the Y-axis direction or a thickness direction of the first display device 1100 and the second display device 1200.

A first lens array 1310 may be disposed between the first display device 1100 and a housing cover 1700. The first lens array 1310 may include a plurality of lenses 1311. The plurality of lenses 1311 may include convex lenses that are convex toward the housing cover 1700.

A second lens array 1410 may be disposed between the second display device 1200 and the housing cover 1700. The second lens array 1410 may include a plurality of lenses 1411. The plurality of lenses 1411 may include convex lenses that are convex toward the housing cover 1700.

A display panel housing 1600 may accommodate the first display device 1100, the second display device 1200, the first lens array 1310 and the second lens array 1410. One surface of the display panel housing 1600 may be opened for accommodating the first display device 1100, the second display device 1200, the first lens array 1310 and the second lens array 1410.

The housing cover 1700 may cover the opened surface of the housing 1600. The housing cover 1700 may include a first opening 1710 where the user's left eye is located and a second opening 1720 where the user's right eye is located. In an embodiment, for example, the first opening 1710 and the second opening 1720 may be formed in a rectangular shape, but the shapes of the first and second openings 1710 and 1720 are not limited thereto. In another embodiment, for example, the first opening 1710 and the second opening 1720 may be formed in a circular shape or an elliptical shape. In another embodiment, for example, the first and second openings 1710 and 1720 may be integrated to form a single opening.

The first opening 1710 may be aligned with the second display device 1200 and the second lens array 1410, and the second opening 1720 may be aligned with the first display device 1100 and the first lens array 1310. Therefore, a user may see virtual images of images on the second display device 1200 magnified by the second lens array 1410 through the first opening 1710, and virtual images of images on the first display device 1100 magnified by the first lens array 1310 through the second opening 1720.

A head strap band 1800 may fix the housing 1600 to the user's head in a way such that the first opening 1710 and the second opening 1720 of the housing cover 1700 are in line with the user's left and right eyes, respectively. The head strap band 1800 may be connected to the top, left and right sides of the housing 1600.

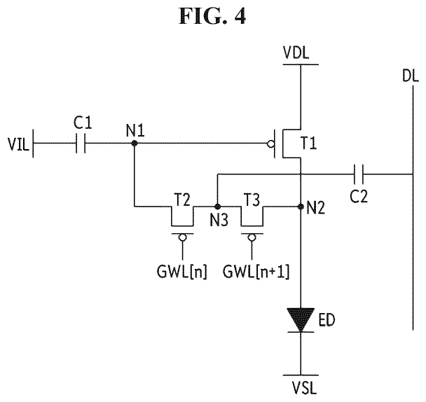

FIG. 4 is a circuit diagram showing a pixel of a display device according to an embodiment of the disclosure.

Referring to FIG. 4, an embodiment of the display device 10 of FIG. 1 or the display device 10 of FIG. 2 may include a plurality of pixels SP. In an embodiment, for example, the pixels SP may be employed by portable electronic devices such as a mobile phone, a smart phone, a tablet personal computer (PC), a mobile communications terminal, an electronic notebook, an electronic book, a portable multimedia player (PMP), a navigation device and a ultra mobile PC (UMPC). In another embodiment, for example, the pixels SP may be applied as a display unit of a television, a laptop computer, a monitor, an electronic billboard, a smart watch, a watch phone, or Internet of Things (IoT).

In an embodiment, a pixel SP may be connected to the n^{th} scan line GWL[n], the (n+1)^{th} scan line GWL[n+1], a data line DL, an initialization voltage line VIL, a driving voltage line VDL, and a low-level voltage line VSL, where n is an integer equal to or greater than two.

The pixel SP may include a light-emitting element ED and a pixel circuit that drives the light-emitting element ED. The pixel circuit may include first to third transistors T1, T2 and T3, and first and second capacitors C1 and C2.

The first transistor T1 may supply a driving current to the light-emitting element ED. The first transistor T1 may include a gate electrode, a source electrode, and a drain electrode. The gate electrode of the first transistor T1 may be connected to a first node N1, the source electrode thereof may be connected to the driving voltage line VDL, and the drain electrode thereof may be connected to a second node N2 that is a first electrode of the light-emitting element ED. The first transistor T1 may control the source-drain current (Isd) (hereinafter, referred to as “driving current”) according to the data voltage applied to the gate electrode. The driving current (Isd) flowing through the channel of the first transistor T1 may be proportional to the square of the difference between the threshold voltage (Vth) and the voltage (Vsg) between the source electrode and the gate electrode of the first transistor T1, that is, the driving current (Isd) satisfies the following equation: Isd=k×(Vsg−Vth)², where Isd denotes the source-drain current, k denotes a proportional coefficient determined by the structure and physical properties of the first transistor T1, Vsg denotes the source-gate voltage of the first transistor T1, and Vth denotes the threshold voltage of the first transistor T1.

The light-emitting element ED may receive the driving current Isd to emit light. The amount or the luminance of the light emitted from the light-emitting element ED may be proportional to the magnitude of the driving current Isd. The light-emitting element ED may include a first electrode, a second electrode, and an emissive layer disposed between the first electrode and the second electrode. The first electrode of the light-emitting element ED may be connected to a second node N2. The first electrode of the light-emitting element ED may be electrically connected to the drain electrode of the first transistor T1 and the drain electrode of the third transistor T3 through the second node N2. The second electrode of the light-emitting element ED may be connected to the low-level voltage line VSL to receive a low-level voltage from it. In an embodiment, for example, the first electrode of the light-emitting element ED may be an anode electrode or a pixel electrode, while the second electrode thereof may be a cathode electrode or a common electrode. However, it would be understood that the disclosure is not limited thereto.

The second transistor T2 may be turned on by the n^{th} scan signal of the n^{th} scan line GWL[n] to electrically connect the first node N1 with a third node N3. A gate electrode of the second transistor T2 may be connected to the n^{th} scan line GWL[n], a source electrode thereof may be connected to the first node N1, and a drain electrode source thereof may be connected to the third node N3. The first node NI may be electrically connected to the first electrode of the first capacitor C1, and the voltage of the first node N1 may be initialized by the initialization voltage line VIL connected to the second electrode of the first capacitor C1. The third node N3 may be electrically connected to a first electrode of the second capacitor C2, and the voltage of the third node N3 may be changed to a voltage equal to the data voltage by the data line DL connected to a second electrode of the second capacitor C2.

The third transistor T3 may be turned on by the (n+1)^{th} scan signal of the (n+1)^{th} scan line GWL[n+1] to electrically connect the third node N3 with the second node N2. A gate electrode of the third transistor T3 may be connected to the (n+1)^{th} scan line GWL[n+1], a source electrode thereof may be connected to the third node N3, and a drain electrode source thereof may be connected to the second node N2.

Each of the first to third transistors T1, T2 and T3 may include a silicon-based active layer. In an embodiment, for example, each of the first to third transistors T1, T2 and T3 may include an active layer made of low-temperature polycrystalline silicon (LTPS). The active layer made of low-temperature polycrystalline silicon may have a high electron mobility and excellent turn-on characteristics. Accordingly, as the display device 10 includes transistors having excellent turn-on characteristics, the plurality of pixels SP can be driven stably and efficiently.

The first to third transistors T1, T2 and T3 may be p-type transistors. In an embodiment, for example, each of the first to third transistors T1, T2 and T3 may output a current flowing into the drain electrode to the drain electrode in response to a gate-low voltage applied to the gate electrode.

In another embodiment, for example, at least one of the first to third transistors T1, T2 and T3 may include an oxide-based active layer. A transistor including an oxide-based active layer may have a coplanar structure in which a gate electrode is disposed at the top. A transistor including an oxide-based active layer may be an n-type transistor and may output current introduced into the drain electrode via the source electrode based on a gate-high voltage applied to the gate electrode.

The first capacitor C1 may be connected between the first node N1 which is the gate electrode of the first transistor T1 and the initialization voltage line VIL. In an embodiment, for example, the first electrode of the first capacitor C1 may be connected to the first node N1, the second electrode of the first capacitor C1 may be connected to the initialization voltage line VIL, such that the potential difference between the gate electrode of the first transistor T1 and the initialization voltage line VIL can be held. Accordingly, the voltage of the first node N1 may be initialized by the initialization voltage line VIL.

The second capacitor C2 may be connected between the third node N3 and the second node N2. In an embodiment, for example, the first electrode of the second capacitor C2 may be connected to the third node N3, the second electrode of the second capacitor C2 may be connected to the data line DL, such that the potential difference between the third node N3 and the data line DL can be maintained. Accordingly, the voltage of the third node N3 may be changed to a voltage equal to the data voltage by the data line DL.

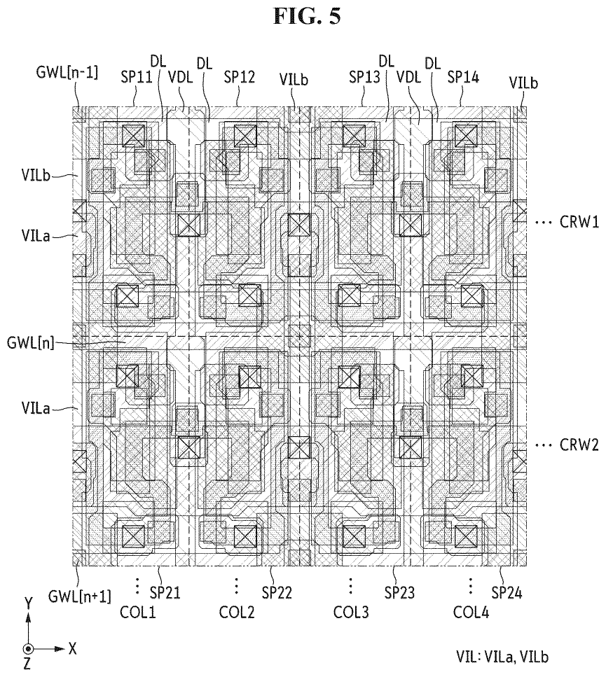

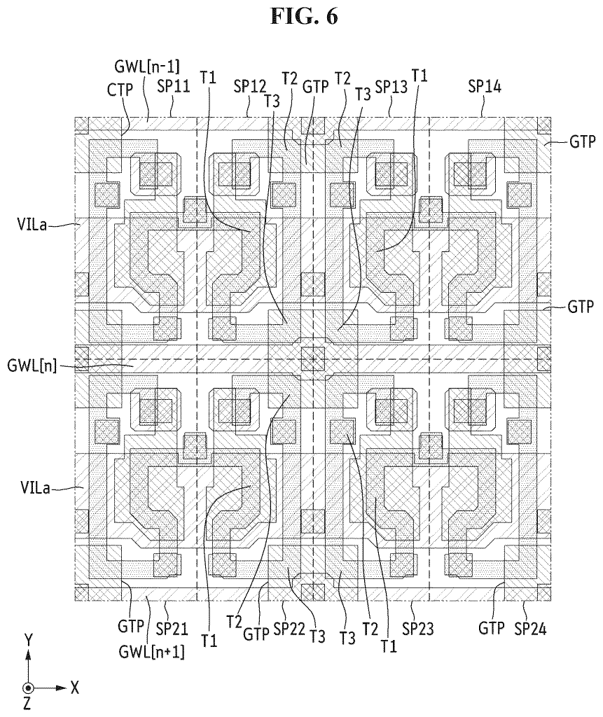

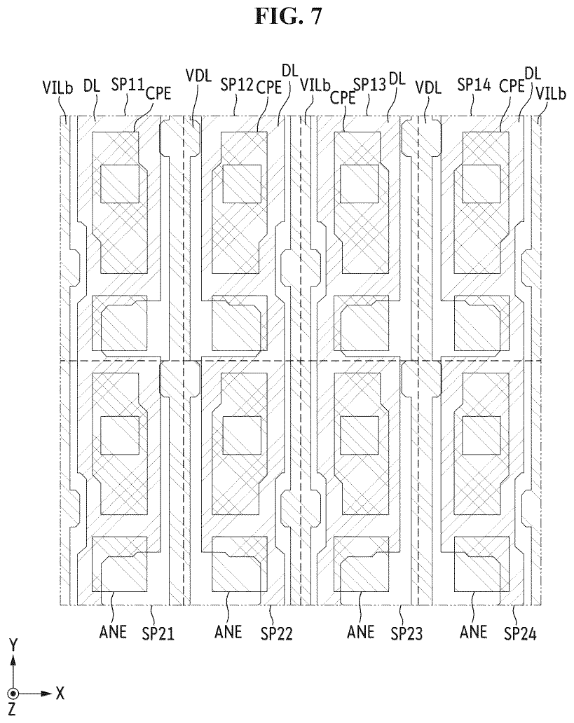

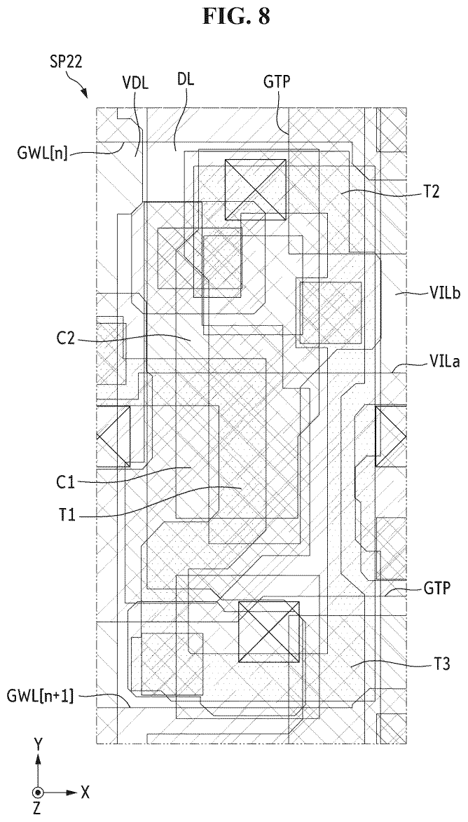

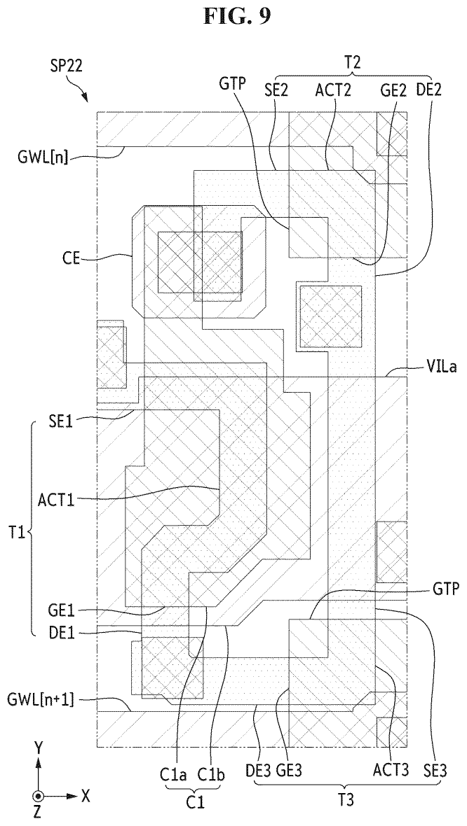

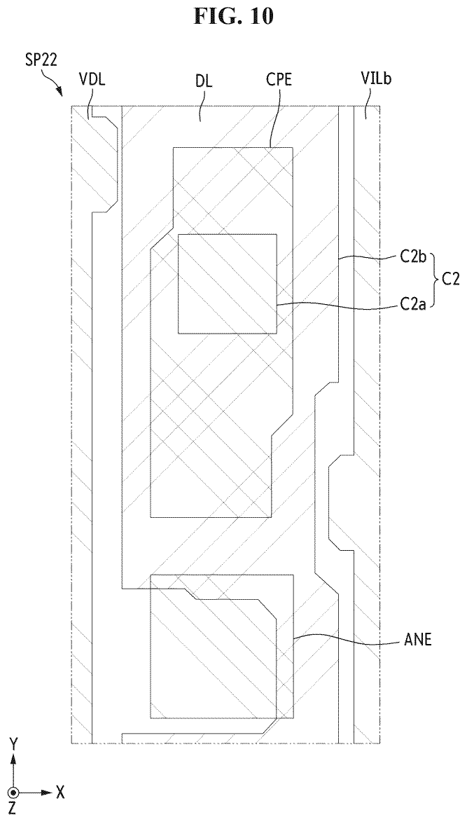

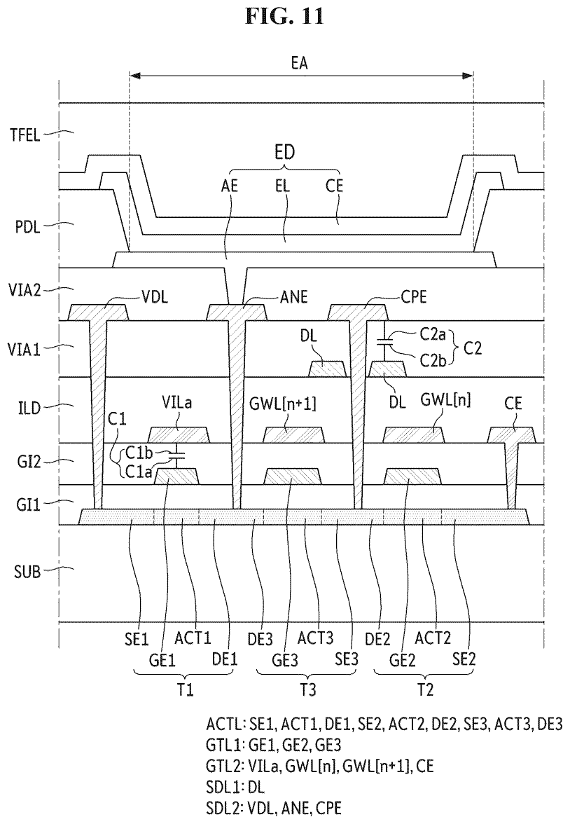

FIG. 5 is a view showing an arrangement of pixels in a display device according to an embodiment of the disclosure. FIG. 6 is a view showing some layers of the view of FIG. 5, especially showing a stacked structure of an active layer ACTL, a first gate layer GTL1, and a second gate layer GTL2. FIG. 7 is a view showing some other layers of the view of FIG. 5, especially showing a stacked structure of a first source metal layer SDL1 and a second source metal layer SDL2. FIG. 8 is a view showing one of pixels of FIG. 5, and is an enlarged view of a 22^{nd} pixel SP22. FIG. 9 is a view showing some layers of the view of FIG. 8, especially showing a stacked structure of an active layer ACTL, a first gate layer GTL1, and a second gate layer GTL2. FIG. 10 is a view showing some other layers of the view of FIG. 8, especially showing a stacked structure of a first source metal layer SDL1 and a second source metal layer SDL2. FIG. 11 is a cross-sectional view showing a pixel in a display device according to an embodiment of the disclosure.

Referring to FIGS. 5 to 11, in an embodiment, the pixels SP may be arranged in rows and columns, that is, in a matrix form. In an embodiment, for example, the pixels SP may be arranged along first and second rows CRW1 and CRW2 and first to fourth columns COL1, COL2, COL3 and COL4. An 11^{th} pixel SP11, a 12^{th} pixel SP12, a 13^{th} pixel SP13 and a 14^{th} pixel SP14 may be disposed in the first row CRW1, and may be electrically connected to the (n−1)^{th} scan line GWL[n−1] and the n^{th} scan line GWL[n]. A 21^{st} pixel SP21, a 22^{nd} pixel SP22, a 23^{rd} pixel SP23 and a 24^{th} pixel SP24 may be disposed in the second row CRW2, and may be electrically connected to the n^{th} scan line GWL[n] and the (n+1)^{th} scan line GWL[n+1]. The pixels SP adjacent to each other in the Y-axis direction (or the second direction) may share one scan line. The n^{th} scan line GWL[n] may be disposed between the first and second rows CRW1 and CRW2.

In an embodiment, as shown in FIG. 6, the n^{th} scan line GWL[n] may supply the n^{th} scan signal to four transistors through one gate pattern GTP. One gate pattern GTP may overlap four pixels SP. One gate pattern GTP may overlap two rows and two columns.

At the center of FIG. 6, one gate pattern GTP may overlap the right lower side of the 12^{th} pixel SP12, the left lower side of the 13^{th} pixel SP13, the right upper side of the 22^{nd} pixel SP22 and the left upper side of the 23^{rd} pixel SP23. In an embodiment, for example, the n^{th} scan line GWL[n] may provide the n^{th} scan signal to the third transistor T3 of the 12^{th} pixel SP, the third transistor T3 of the 13^{th} pixel SP, the second transistor T2 of the 22^{nd} pixel SP22, and the second transistor T2 of the 23^{rd} pixel SP23 via one gate pattern GTP. Accordingly, the n^{th} scan line GWL[n] may provide the n^{th} scan signal to both the first and second rows CRW1 and CRW2, and thus the number of the scan lines in the display device 10 may be reduced and the area of the pixel circuit may be reduced. In this manner, a high-resolution display device can be effectively implemented.

In an embodiment, as shown in FIG. 7, the data line DL may be extending in the Y-axis direction. Each of the plurality of data lines DL may be associated with one column. The pixels SP arranged in each of the first to fourth columns COL1, COL2, COL3 and COL4 may receive a data voltage from one data line DL.

The driving voltage line VDL may be extending in the Y-axis direction. The pixels SP adjacent to each other in the X-axis direction (or the first direction) may share one driving voltage line VDL. One driving voltage line VDL may be disposed between the first and second columns COL1 and COL2 to provide a driving voltage to the 11^{th}, 12^{th}, 21^{st} and 22^{nd} pixels SP11, SP12, SP21 and SP22. Another driving voltage line VDL may be disposed between the third and fourth columns COL3 and COL4 and may provide a driving voltage to the 13^{th}, 14^{th}, 23^{rd} and 24^{th} pixels SP13, SP14, SP23 and SP24.

The active layer ACTL of the 11^{th} pixel SP11 and the active layer ACTL of the 12^{th} pixel SP12 may be symmetrical about the axis in the Y-axis direction. The source electrode SE1 of the first transistor T1 of the 11^{th} pixel SP11 and the source electrode SE1 of the first transistor T1 of the 12^{th} pixel SP12 may be formed integrally with each other as a single unitary indivisible part. Accordingly, the pixels SP arranged in the first and second columns COL1 and COL2 may share one driving voltage line VDL, and the source electrode SE1 of the first transistor T1 of each of the 11^{th} pixel SP11 and the 12^{th} pixel SP12 may receive a driving voltage through one driving voltage line VDL.

The active layer ACTL of the 13^{th} pixel SP13 and the active layer ACTL of the 14^{th} pixel SP14 may be symmetrical about the axis in the Y-axis direction. The source electrode SE1 of the first transistor T1 of the 13^{th} pixel SP13 and the source electrode SE1 of the first transistor T1 of the 14^{th} pixel SP12 may be formed integrally with each other as a single unitary indivisible part. Accordingly, the pixels SP arranged in the third and fourth columns COL3 and COL4 may share one driving voltage line VDL, and the source electrode SE1 of the first transistor T1 of each of the 13^{th} pixel SP13 and the 14^{th} pixel SP14 may receive a driving voltage through one driving voltage line VDL. Accordingly, the area of the pixel circuit may be reduced in the display device 10 by reducing the number of the driving voltage lines VDL, such that a high-resolution display device may be effectively implemented.

The initialization voltage line VIL may include a first portion VILa and a second portion VILb. The first portion VILa of the initialization voltage line VIL may be disposed in the second gate layer GTL2 and extending in the X-axis direction. Each of the first portions VILa of the plurality of initialization voltage lines VIL may be associated with one row. The pixels SP disposed in each of the first and second rows CRW1 and CRW2 may receive an initializing voltage from the first portion VILa of one initialization voltage line VIL.

The second portion VILb of the initialization voltage line VIL may be disposed in the second source metal layer SDL2 and extending in the Y-axis direction, and may be electrically connected to the first portion VILa of the initialization voltage line VIL. The second portion VILb of one initialization voltage line VIL may be disposed between adjacent pixels SP in the X-axis direction. In an embodiment, for example, the second portion VILb of one initialization voltage line VIL may be disposed between the second and third columns COL2 and COL3. The second portion VILb of one initialization voltage line VIL may be disposed between adjacent driving voltage lines VDL in the X-axis direction. The area of the pixel circuit in the display device 10 may be reduced by reducing the number of the initialization voltage lines VIL, such that a high-resolution display device may be effectively implemented.

Referring to FIGS. 8 to 10, the 22^{nd} pixel SP22 may be connected to the n^{th} scan line GWL[n], the (n+1)^{th} scan line GWL[n+1], the data line DL, the initialization voltage line VIL, the driving voltage line VDL and the low-level voltage line VSL.

In an embodiment, as shown in FIG. 9, the first transistor T1 may include a semiconductor region ACT1, a source electrode SE1, a drain electrode DE1 and a gate electrode GE1. The semiconductor region ACT1, the source electrode SE1 and the drain electrode DE1 of the first transistor T1 may be disposed in (or defined by portions of) the active layer ACTL, and the gate electrode GE1 of the first transistor T1 may be disposed in (or defined by portions of) the first gate layer GTL1. The gate electrode GEI of the first transistor T1 may overlap the semiconductor region ACT1 of the first transistor T1. In an embodiment, for example, the semiconductor region ACT1 of the first transistor T1 may include low-temperature polycrystalline silicon, and the source electrode SE1 and the drain electrode DE1 of the first transistor T1 may be formed by p-type doping.

The gate electrode GE1 of the first transistor T1 may be electrically connected to the source electrode SE2 of the second transistor T2 through a connection electrode CE of the second gate layer GTL2. The gate electrode GE1 of the first transistor T1 may be a portion of the first electrode C1a of the first capacitor C1, and the second electrode C1b of the first capacitor C1 may be a portion of the first portion VILa of the initialization voltage line VIL disposed in the second gate layer GTL2. Accordingly, the first capacitor C1 may initialize the gate electrode GE1 of the first transistor T1 with a voltage equal to an initializing voltage. The source electrode SE1 of the first transistor T1 may be connected to the driving voltage line VDL of the second source metal layer SDL2. The drain electrode DE1 of the first transistor T1 may be formed integrally with a drain electrode DE3 of the third transistor T3 as a single unitary indivisible part. The drain electrode DE1 of the first transistor T1 may be electrically connected to the first electrode AE of the light-emitting element ED through an anode connection electrode ANE of the second source metal layer SDL2.

The second transistor T2 may include a semiconductor region ACT2, a source electrode SE2, a drain electrode DE2 and a gate electrode GE2. The semiconductor region ACT2, the source electrode SE2 and the drain electrode DE2 of the second transistor T2 may be disposed in (or defined by portions of) the active layer ACTL, and the gate electrode GE2 of the second transistor T2 may be disposed in (or defined by portions of) the first gate layer GTL1. The gate electrode GE2 of the second transistor T2 may overlap the semiconductor region ACT2 of the second transistor T2. In an embodiment, for example, the semiconductor region ACT2 of the second transistor T2 may include low-temperature polycrystalline silicon, and the source electrode SE3 and the drain electrode DE2 of the second transistor T2 may be formed by p-type doping.

The gate electrode GE2 of the second transistor T2 may be a portion of the gate pattern GTP that overlaps the first and second rows CRW1 and CRW2. The second transistor T2 of the 22^{nd} pixel SP22 may receive the n^{th} scan signal of the n^{th} scan line GWL[n] through the gate pattern GTP. The source electrode SE2 of the second transistor T2 may be electrically connected to the gate electrode GE1 of the first transistor T1 through the connection electrode CE. The drain electrode DE2 of the second transistor T2 may be formed integrally with a source electrode SE3 of the third transistor T3 as a single unitary indivisible part. The drain electrode DE2 of the second transistor T2 may be connected to the capacitor electrode CPE of the second source metal layer SDL2. The capacitor electrode CPE may be the first electrode C2a of the second capacitor C2, and the data line DL may be disposed in the first source metal layer SDL1 and may include the second electrode C2b of the second capacitor C2. The capacitor electrode CPE may be connected to the drain electrode DE2 of the second transistor T2 through a hole defined or formed in the data line DL. Accordingly, the second capacitor C2 may change the drain electrode DE2 of the second transistor T2 and the source electrode SE3 of the third transistor T3 with a voltage equal to the data voltage.

The third transistor T3 may include a semiconductor region ACT3, a source electrode SE3, a drain electrode DE3 and a gate electrode GE3. The semiconductor region ACT3, the source electrode SE3 and the drain electrode DE3 of the third transistor T3 may be disposed in (or defined by portions of) the active layer ACTL, and the gate electrode GE3 of the third transistor T3 may be disposed in (or defined by portions of) the first gate layer GTL1. The gate electrode GE3 of the third transistor T3 may overlap the semiconductor region ACT3 of the third transistor T3. In an embodiment, for example, the semiconductor region ACT3 of the third transistor T3 may include low-temperature polycrystalline silicon, and the source electrode SE3 and the drain electrode DE3 of the third transistor T3 may be formed by p-type doping.

The gate electrode GE3 of the third transistor T3 may be a portion of the gate pattern GTP that overlaps with the second row CRW2 and a third row (not shown). The third transistor T3 of the 22^{nd} pixel SP22 may receive the (n+1)^{th} scan signal of the (n+1)^{th} scan line GWL[n+1] through the gate pattern GTP. The source electrode SE3 of the third transistor T3 may be formed integrally with the drain electrode DE2 of the second transistor T2 as a single unitary indivisible part. The source electrode SE3 of the third transistor T3 may be connected to the capacitor electrode CPE. The capacitor electrode CPE may be connected to the source electrode SE3 of the third transistor T3 through the hole defined or formed in the data line DL. The drain electrode DE3 of the third transistor T3 may be formed integrally with the drain electrode DE1 of the first transistor T1 as a single unitary indivisible part. The drain electrode DE3 of the third transistor T3 may be electrically connected to the first electrode AE of the light-emitting element ED through an anode connection electrode ANE.

The first capacitor C1 may include the first electrode C1a and a second electrode C1b. The first and second electrodes C1a and Cb of the first capacitor C1 may overlap each other. The first electrode C1a of the first capacitor C1 may be disposed in (or defined by portions of) the first gate layer GTL1, and the second electrode C1b may be disposed in (or defined by portions of) the second gate layer GTL2. The first electrode C1a of the first capacitor C1 may include the gate electrode GE1 of the first transistor T1, and the second electrode C1b may be a portion of the first portion VILa of the initialization voltage line VIL. Accordingly, the first capacitor C1 may maintain a potential difference between the gate electrode GE1 of the first transistor T1 and the initialization voltage line VIL.

The second capacitor C2 may include the first electrode C2a and the second electrode C2b. The first and second electrodes C2a and C2b of the second capacitor C2 may overlap each other. The first electrode C2a of the second capacitor C2 may be disposed in (or defined by portions of) the second source metal layer SDL2, and the second electrode C2b may be disposed in (or defined by portions of) the first source metal layer SDL1. The first electrode C2a of the second capacitor C2 may be a capacitor electrode CPE, and the second electrode C2b of the second capacitor C2 may be a portion of the data line DL. Accordingly, the second capacitor C2 may maintain a potential difference between the drain electrode DE2 of the second transistor T2 and the data line DL.

In an embodiment, as shown in FIG. 11, the display device 10 may include a metal layer BML, a buffer layer BF, an active layer ACTL, a first gate insulator GI1, a first gate layer GTL1, a second gate insulator GI2, a second gate layer GTL2, an interlayer dielectric layer ILD, a first source metal layer SDL1, a first via layer VIA1, a second source metal layer SDL2, a second via layer VIA2, a pixel-defining layer PDL, a light-emitting element ED, and an encapsulation layer TFEL.

The substrate SUB may be a base substrate or a base member. The substrate SUB may be a flexible substrate that can be bent, folded, or rolled. In an embodiment, for example, the substrate SUB may include a glass material, but the constituent material of the substrate SUB is not limited thereto. In another embodiment, for example, the substrate SUB may include a polymer resin such as polyimide PI.

The active layer ACTL may be disposed on the substrate SUB. The active layer ACTL may include a silicon-based material. The active layer ACTL may include the semiconductor regions ACT1, ACT2 and ACT3, the source electrodes SE1, SE2 and SE3, and the drain electrodes DE1, DE2 and DE3 of the first to third transistors T1, T2 and T3, respectively.

The first gate insulator GI1 may be disposed on the active layer ACTL. The first gate insulator GI1 may insulate the active layer ACTL from the first gate layer GTL1.

The first gate layer GTL1 may be disposed on the first gate insulator GI1. The first gate layer GTL1 may include the gate electrodes GE1, GE2 and GE3 of the first to third transistors T1, T2 and T3, respectively.

The second gate insulator GI2 may be disposed on the first gate layer GTL1. The second gate insulator GI2 may insulate the first gate layer GTL1 from the second gate layer GTL2.

The second gate layer GTL2 may be disposed on the second gate insulator GI2. The second gate layer GTL2 may include or define the n^{th} scan line GWL[n], the (n+1)^{th} scan line GWL[n+1], a connection electrode CE, and a first portion VILa of an initialization voltage line VIL.

The interlayer dielectric layer ILD may be disposed on the second gate layer GTL2. The second interlayer dielectric layer ILD2 may insulate the second gate layer GTL2 from the first source metal layer SDL1.

The first source metal layer SDL1 may be disposed on the interlayer dielectric layer ILD. The first source metal layer SDL1 may include or define a data line DL.

The first via layer VIA1 may be disposed on the first source metal layer SDL1. The first via layer VIA1 may insulate the first source metal layer SDL1 from the second source metal layer SDL2.

The second source metal layer SDL2 may be disposed on the first via layer VIA1. The second source metal layer SDL2 may include or define a driving voltage line VDL, an anode connection electrode ANE, and a capacitor electrode CPE.

The second via layer VIA2 may be disposed on the second source metal layer SDL2. The second via layer VIA2 may insulate the second source metal layer SDL2 from the first electrode AE of the light-emitting element ED.

The emission material layer EDL may include a pixel-defining layer PDL and light-emitting elements ED. The light-emitting element ED may include a first electrode AE, an emissive layer EL, and a second electrode CAT.

The pixel-defining layer PDL may be disposed on the second via layer VIA2. The pixel-defining layer PDL may define a plurality of emission areas EA. The pixel-defining layer PDL may include an organic insulating material such as polyimide (PI).

The first electrode AE may be disposed on the second via layer VIA2. The first electrode AE may overlap one of the plurality of emission areas EA defined by the pixel-defining layer PDL. The first electrode AE may be connected to the anode connection electrode ANE and may receive a driving current from the pixel circuit of the pixel SP.

The emissive layer EL may be disposed on the first electrode AE. In an embodiment, for example, the emissive layer EL may be, but is not limited to, an organic emissive layer made of an organic material. In an embodiment where the emissive layer EL is an organic light-emitting layer, when the pixel circuit of the pixel SP applies a predetermined voltage to the first electrode AE and the second electrode CAT receives a common voltage or cathode voltage, holes may move to the organic light-emitting layer EL through a hole transporting layer and electrons may move to the organic light-emitting layer EL through a hole transporting layer, and the holes and the electrons are combined with each other in the organic light-emitting layer EL to emit light.

The second electrode CAT may be disposed on the emissive layer EL. In an embodiment, for example, the second electrode CAT may be implemented in the form of a common electrode extending across all of the pixels SP, instead of being disposed separately in each of the pixels SP. The second electrode CAT may be disposed on the emissive layer EL in the emission areas EA and may be disposed on the pixel-defining layer PDL except for the emission areas EA.

The encapsulation layer TFEL may be disposed on the second electrode CAT to cover the light-emitting diodes ED. The encapsulation layer TFEL may include at least one inorganic film to prevent permeation of oxygen or moisture into the light-emitting elements ED. The encapsulation layer TFEL may include at least one organic film to protect the light-emitting elements ED from particles such as dust.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a first pixel disposed in a first row and a first column;
a second pixel disposed in the first row and a second column next to the first column;
a third pixel disposed in a second row next to the first row and the first column;
a fourth pixel disposed in the second row and the second column;
a first scan line extending in a first direction between the first row and the second row; and
a first gate pattern connected to the first scan line,
wherein the first gate pattern comprises a gate electrode of a transistor of each of the first to fourth pixels.

2. The display device of claim 1, further comprising:
a second scan line disposed on a lower side of the second row and extending in the first direction; and
a second gate pattern connected to the second scan line,
wherein the second gate pattern comprises a gate electrode of another transistor of each of the third and fourth pixels.

3. The display device of claim 2, further comprising:
an initialization voltage line which supplies an initialization voltage;
a driving voltage line which supplies a driving voltage; and
a data line which supplies a data voltage,
wherein each of the first to fourth pixels comprises:
a light-emitting element disposed on a substrate;
a first transistor which supplies a driving current to a second node connected to a first electrode of the light-emitting element, based on a voltage of a first node connected to a gate electrode thereof;
a first capacitor connected between the first node and the initialization voltage line;
a second transistor connected to the first node;
a second capacitor connected between the data line and a third node, which is connected to a drain electrode of the second transistor; and
a third transistor connected between the third node and the second node.

4. The display device of claim 3, wherein the first scan line supplies a first scan signal to the third transistor of the first pixel, the third transistor of the second pixel, the second transistor of the third pixel and the second transistor of the fourth pixel through the first gate pattern.

5. The display device of claim 3, wherein the second scan line supplies a second scan signal to the third transistor of the third pixel and the third transistor of the fourth pixel through the second gate pattern.

6. The display device of claim 3, further comprising:
an active layer disposed on the substrate and comprising a semiconductor region of each of the first to third transistors;
a first gate layer disposed on the active layer and comprising the gate electrode of each of the first to third transistors;
a second gate layer disposed on the first gate layer and comprising the first and second scan lines;
a first source metal layer disposed on the second gate layer; and
a second source metal layer disposed on the first source metal layer.

7. The display device of claim 6, wherein the first gate pattern is defined by the first gate layer and comprises the gate electrode of the third transistor of the first pixel, the gate electrode of the third transistor of the second pixel, the gate electrode of the second transistor of the third pixel, and the gate electrode of the second transistor of the fourth pixel.

8. The display device of claim 6, wherein the second gate pattern is defined by the first gate layer and comprises the gate electrode of the third transistor of the third pixel and the gate electrode of the third transistor of the fourth pixel.

9. The display device of claim 6, wherein the initialization voltage line comprises a first portion defined by the second gate layer and extending in the first direction; and a second portion defined by the second source metal layer, intersecting the first direction, and connected to the first portion.

10. The display device of claim 9, wherein
a first electrode of the first capacitor comprises the gate electrode of the first transistor, and
a second electrode of the first capacitor is a portion of the first portion of the initialization voltage line.

11. The display device of claim 6, further comprising:
a capacitor electrode disposed on the second source metal layer,
wherein the data line is defined by the first source metal layer, and
wherein a first electrode of the second capacitor is the capacitor electrode, and a second electrode of the second capacitor is a portion of the data line.

12. A display device comprising:
a first pixel disposed in a first row and a first column;
a second pixel disposed in the first row and a second column next to the first column;
a third pixel disposed in the first row and a third column next to the second column;
a fourth pixel disposed in a second row next to the first row and the first column;
a fifth pixel disposed in the second row and second column;
a sixth pixel disposed in the second row and third column;
a first scan line extending in a first direction between the first row and the second row;
a first gate pattern connected to the first scan line and overlapping the second, third, fifth and sixth pixels; and
a driving voltage line extending between the first column and the second column in
a second direction intersecting the first direction,
wherein the driving voltage line supplies a driving voltage to the first, second, fourth and fifth pixels.

13. The display device of claim 12, further comprising:
an initialization voltage line which supplies an initialization voltage; and
a data line which supplies a data voltage,
wherein each of the first to sixth pixels comprises:
a light-emitting element disposed on a substrate;
a first transistor which supplies a driving current to a second node connected to a first electrode of the light-emitting element based on a voltage of a first node connected to a gate electrode thereof;
a first capacitor connected between the first node and the initialization voltage line;
a second transistor connected to the first node;
a second capacitor connected between the data line and a third node connected to a drain electrode of the second transistor; and
a third transistor connected between the third node and the second node.

14. The display device of claim 13, wherein a source electrode of the first transistor of the first pixel and a source electrode of the first transistor of the second pixel are formed integrally with each other as a single unitary indivisible part, and
wherein the driving voltage line supplies a driving voltage to the source electrode of the first transistor of each of the first and second pixels.

15. The display device of claim 13, wherein the first gate pattern comprises a gate electrode of the third transistor of the second pixel, a gate electrode of the third transistor of the third pixel, a gate electrode of the second transistor of the fifth pixel, and a gate electrode of the second transistor of the sixth pixel.

16. The display device of claim 13, further comprising:
a second scan line disposed on a lower side of the second row and extending in the first direction; and
a second gate pattern connected to the second scan line,
wherein the second gate pattern overlaps the fifth and sixth pixels.

17. The display device of claim 16, wherein the first gate pattern comprises a gate electrode of the third transistor of the fifth pixel and a gate electrode of the third transistor of the sixth pixel.

18. The display device of claim 16, further comprising:
an active layer disposed on the substrate and comprising a semiconductor region of each of the first to third transistors;
a first gate layer disposed on the active layer and comprising a gate electrode of each of the first to third transistors;
a second gate layer disposed on the first gate layer and comprising the first and second scan lines;
a first source metal layer disposed on the second gate layer; and
a second source metal layer disposed on the first source metal layer.

19. The display device of claim 18, wherein the initialization voltage line comprises: a first portion defined by the second gate layer and extending in the first direction; and a second portion defined by the second source metal layer, intersecting the first direction, and connected to the first portion.

20. The display device of claim 19, wherein a first electrode of the first capacitor comprises the gate electrode of the first transistor, and a second electrode of the first capacitor is a part of the first portion of the initialization voltage line.
